(19) United States
(12) Patent Application Publication
(10) Pub. No.: US 2026/0064923 A1
(43) Pub. Date: Mar. 5, 2026

(54) PROCESS SIMULATION ASSISTANT AGENT BASED ON GENERATIVE AI

(71) Applicant: Schlumberger Technology Corporation, Sugar Land, TX (US)

(72) Inventors: Raul Carlos Cota Elizondo, Calgary (CA); Prasham Sheth, Menlo Park, CA (US); Caleb Andrew Bell, Calgary (CA)

(21) Appl. No.: 19/286,507

(22) Filed: Jul. 31, 2025

Related U.S. Application Data
(60) Provisional application No. 63/689,083, filed on Aug. 30, 2024.

(51) Int. Cl. G06F 30/28; G06F 30/27

(52) U.S. Cl. CPC G06F 30/28; G06F 30/27

(57) ABSTRACT

A method for simulating a process in a new or existing oil and/or gas processing facility includes receiving a user prompt from a user with an application. The method also includes transmitting the user prompt from the application to a trained large language model (LLM) agent. The method also includes transmitting suggested tool values and/or suggested parameter values from the trained LLM agent to the application based upon the user prompt. The method also includes transmitting a tool request from the application to a simulator based upon and/or in response to the suggested tool values and/or the suggested parameter values. The method also includes transmitting a tool output from the simulator to the application to the trained LLM agent based upon and/or in response to the tool request. The method also includes generating a response based upon the user prompt and the tool output using the trained LLM agent.

### CROSS-REFERENCE TO RELATED APPLICATIONS

This application claims priority to U.S. Provisional Patent Application No. 63/689,083, filed on Aug. 30, 2024, which is incorporated by reference.

### BACKGROUND

Process engineers often know what they want from a process simulator but do not have the expertise or time to obtain it. The same situation happens with automated systems where data and measurements are present, but the interpretation of this information would involve the automatic creation of specialized process simulations to automatically generate a root cause analysis and suggestion for an action plan. Therefore, what is needed is a process simulation assistant agent that uses generative artificial intelligence.

### SUMMARY

A method for simulating a process in a new or existing oil and/or gas processing facility is disclosed. The method includes receiving a user prompt from a user with an application. The method also includes transmitting the user prompt from the application to a trained large language model (LLM) agent. The method also includes transmitting suggested tool values and/or suggested parameter values from the trained LLM agent to the application based upon and/or in response to the user prompt. The method also includes transmitting a tool request from the application to a simulator based upon and/or in response to the suggested tool values and/or the suggested parameter values. The method also includes transmitting a tool output from the simulator to the application to the trained LLM agent based upon and/or in response to the tool request. The method also includes generating a response based upon and/or in response to the user prompt and the tool output using the trained LLM agent.

In another embodiment, the method includes receiving input data. The input data is related to the new or existing oil and/or gas processing facility. The input data includes text, voice, sound, and/or images. The input data is received from an artificial intelligence (AI) agent or from a user that is typing or talking into a microphone. The method also includes training a large language model (LLM) agent to reason and act based upon the input data to produce a trained LLM agent. The method also includes receiving a user prompt from the user with an application. The user prompt includes an instruction or a question related to the new or existing oil and/or gas processing facility. The instruction or the question is related to: (1) simulating a plurality of different scenarios of dehydrating and conditioning of a natural gas stream to make it suitable for transport; (2) simulating a plurality of different scenarios of processing multiple crude feedstocks to produce one or more products that meet predetermined specifications; or (3) simulating a plurality of different scenarios of determining emissions of equipment in response to using different energy sources. The method also includes transmitting the user prompt, a system prompt, and tools information from the application to the trained LLM agent. The system prompt includes instructions and guidelines for the trained LLM agent along with domain knowledge for a backend code of a simulator that (1) guides the trained LLM agent on how to behave for the different scenarios, (2) restricts a scope of the trained LLM agent to focus on a specific domain, and (3) acts as a safeguard for any vulnerable prompts. The tools information relates to different tools that are available. The tools are used to fetch curated domain knowledge documents related to understanding different functionalities of different operations used in the new or the existing oil and/or gas processing facility. The curated domain knowledge documents are also related to the backend code and properties of the different operations used in the new or the existing oil and/or gas processing facility supported by the simulator. The curated domain knowledge documents include a user manual for the simulator. The tools also fetch relevant portions from the curated domain knowledge documents by querying a vector store to determine a similarity score to rank a relevance of the portions. The tools execute the backend code on the simulator by: (1) fetching a current state of the simulator; (2) generating the backend code based upon the user prompt and the current state of the simulator; (3) executing the generated backend code to interact with the simulator using preexisting HTTP APIs and/or pre-existing SDK; and (4) generating follow-up scenarios in response to executing the generated backend code. The method also includes transmitting suggested tool values and suggested parameter values from the trained LLM agent to the application based upon and/or in response to the user prompt, the system prompt, and the tools information. The suggested tool values include names of the tools. The suggested parameter values include values and specifications that guide behavior of the tools. The method also includes transmitting a tool request from the application to the simulator based upon and/or in response to the user prompt, the suggested tool values, and the suggested parameter values. The simulator is configured to execute the backend code in response to the tool request. The method also includes transmitting a tool output from the simulator to the application based upon and/or in response to the tool request. The tool output includes responses from the tools. The method also includes transmitting the tool output from the application to the trained LLM agent. The method also includes generating a response based upon and/or in response to the user prompt and the tool output using the trained LLM agent. The response includes text (1) summarizing the response, (2) describing one or more actions to be performed by the simulator, and/or (3) describing changes to make to the generated backend code. The method also includes transmitting the response from the trained LLM agent to the application. The method also includes displaying the response to the user on a user interface of the application. The method also includes performing an action based upon and/or in response to the response, wherein the action is determined by the trained LLM agent, wherein the action comprises generating and/or transmitting a signal using the application that recommends, instructs, or causes a physical action to occur.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 illustrates a diagram of the components and the flow of information for the process simulation assistant, according to an embodiment.

FIGS. 3A and 3B illustrate images of a user making a request to the assistant connected to the process simulator, according to an embodiment.

FIGS. 4A and 4B illustrate images of the assistant proposing an action and explaining the action, according to an embodiment.

FIGS. 5A and 5B illustrate the assistant being asked to perform the action and the creation of the simulation, according to an embodiment.

FIG. 6 illustrates a schematic view of a system for creating a process simulation, according to an embodiment.

FIG. 7A illustrates the system performing a general process simulation, and FIG. 7B illustrates the system performing a specific example of a process simulation, according to an embodiment.

FIG. 8A illustrates an example of a simulator manual, and FIG. 8B illustrates an example of a model creation, according to an embodiment.

FIG. 9 illustrates a flowchart of a method for simulating a process in a new or existing oil and/or gas processing facility, according to an embodiment.

FIG. 10 illustrates a schematic view of a computing system for performing at least a portion of the method(s) described herein, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

### System Overview

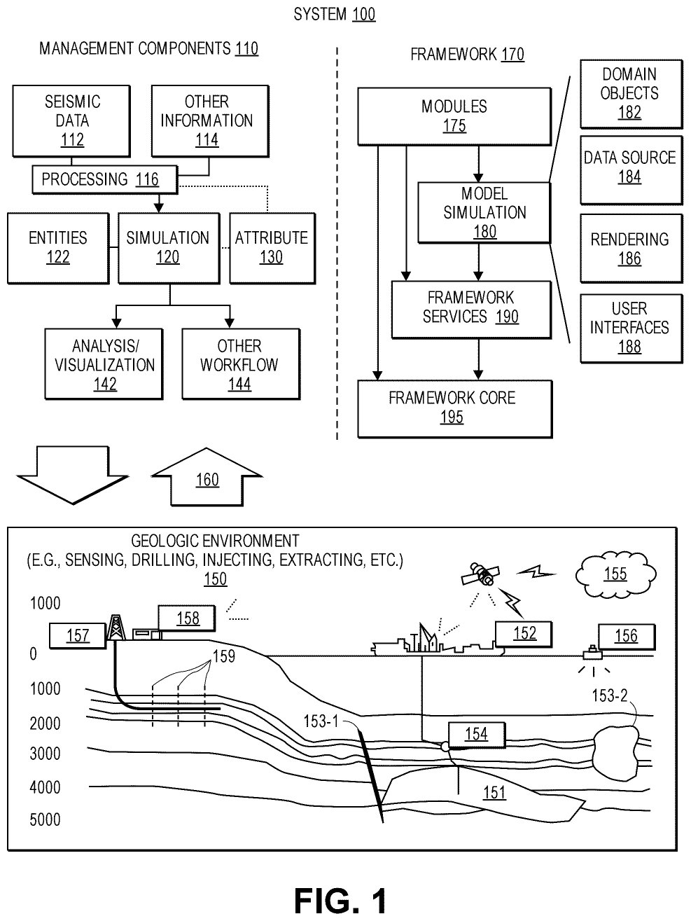

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 can include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT® NET® framework (Redmond, Washington), which provides a set of extensible object classes. In the NET® framework, an object class encapsulates a module of reusable code and associated data structures. Object classes can be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (SLB, Houston Texas), the INTERSECT™ reservoir simulator (SLB, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

As an example, the simulation component 120 may include one or more features of a simulator such as SYMMETRY software (SLB, Houston, Texas). More particularly, SYMMETRY may process workflows in a single integrated environment with accurate thermodynamic fluid representation and consistent modeling across multiple disciplines including process, production, and HSE. The simulator integrates steady-state and transient (e.g., dynamic) analyses that can be tailored for each domain. This approach enables users to optimize processes in upstream, midstream, and downstream sectors while maximizing profits and minimizing capital expenditures. It may also help reduce emissions, energy consumption, and waste.

As an example, the simulation component 120 may include one or more features of a simulator such as PIPESIM (SLB, Houston, Texas). More particularly, PIPESIM is steady-state multiphase flow simulator that incorporates the three areas of flow modeling: multiphase flow, heat transfer and fluid behavior.

As an example, the simulation component 120 may include one or more features of a simulator such as OLGA™ (SLB, Houston, Texas). More particularly, OLGA™ is a dynamic multiphase flow simulator that models transient flow (e.g., time-dependent behaviors) to maximize production potential. Transient modeling is a component for feasibility studies and field development design. Dynamic simulation is useful in deep water and is used in both offshore and onshore developments to investigate transient behavior in pipelines and wellbores. Transient simulation with the OLGA™ simulator provides an added dimension to steady-state analysis by predicting system dynamics, such as time-varying changes in flow rates, fluid compositions, temperature, solids deposition, and operational changes.

In an example embodiment, the management components 110 may include features of a commercially available framework such as the PETREL® seismic to simulation software framework (SLB, Houston, Texas). The PETREL® framework provides components that allow for optimization of exploration and development operations. The PETREL® framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN® framework environment (SLB, Houston, Texas) allows for integration of add-ons (or plug-ins) into a PETREL® framework workflow. The OCEAN® framework environment leverages .NET® tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN® framework applications. In an example embodiment, the PETREL® software may be considered a data-driven application. The PETREL® software can include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

As an example, the domain objects 182 can include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project can be accessed and restored using the model simulation layer 180, which can recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

### Process Simulation Assistant Agent Based on Generative AI

The present disclosure allows non-experts to create process simulations at an expert level for multiple applications such as design, troubleshooting, and/or optimization of facilities. More particularly, the method described herein uses a customized generative artificial intelligence (AI) model, also known as a large language model (LLM), to allow users with little to no experience with process simulators to create process simulations capable of designing new processes or optimizing an existing operating facility. The consumer of this application can be a human or another LLM agent that desires simulations of facilities. The training methodology for the LLM may be capable of creating process simulations with generic text or images. In addition, this LLM agent can be orchestrated by another LLM agent that desires specialized process simulation services.

A process simulation assistant may help users with little to no knowledge of process simulators perform a partial or complete simulation of a processing facility. With the process simulation assistant, process engineers can become more efficient at designing or optimizing a facility by increasing productivity and reducing training costs. This same assistant can also be consumed by non-humans as a specialized process simulation agent that is part of a comprehensive solution for the safe and profitable operation of an entire facility. The process simulation assistant can take input in a variety of formats such as text instructions, images, and measurements. This information can then be translated into digital instructions to create or modify a process simulation to generate insights that satisfy the request.

The LLM may then be trained with specific knowledge on the process simulator of choice such that the LLM can interpret input information and drive the simulator to perform any relevant task. Example applications include the creation of a smart assistant for users where the user can provide prompts similar to:
“I would like to create a simulation for a dehydration process of a natural gas that contains 80% methane, 10% CO₂, 5% H₂S and the rest are light hydrocarbons,” and the assistant would create a simulation that matches these conditions and explain the choices made.
“The current simulation includes a carbon capture plant and a compression system. Create an optimization objective function and choose appropriate manipulated variables to reduce emissions and energy consumption”. “I have a drawing of a facility, create a simulation of the process”
“Can you explain how to create a de-pressuring case for a vessel with hydrogen?”
“I have laboratory data for an oil in a pdf file. Please create a characterization case and create an equation of state along with its composition and define it in a material stream”

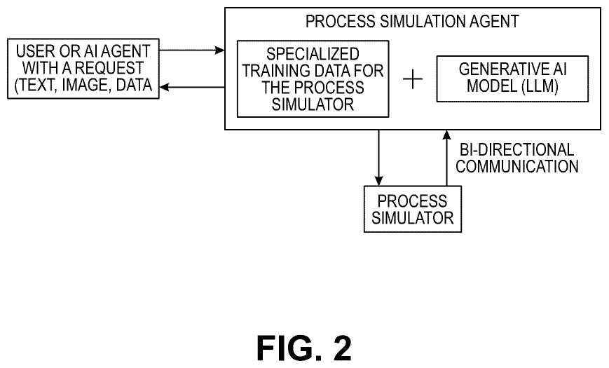

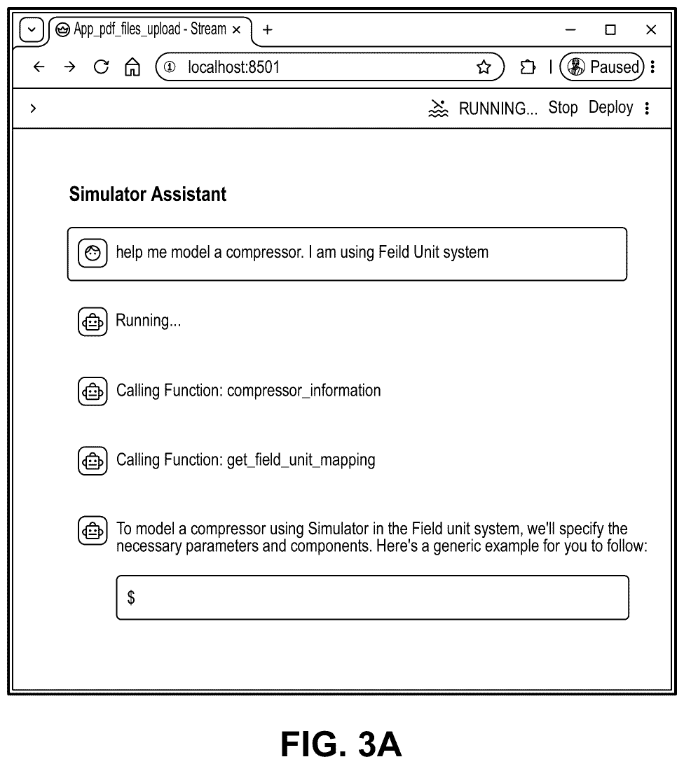

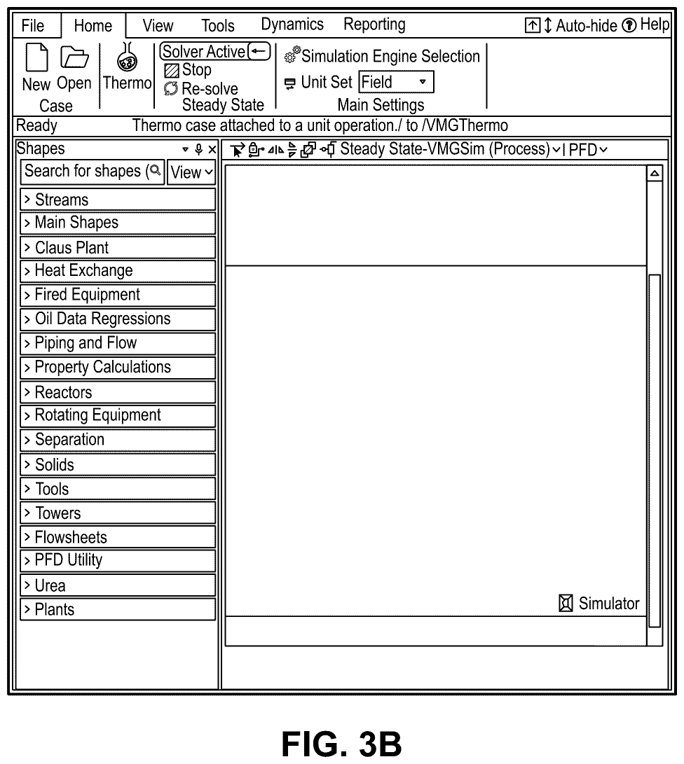

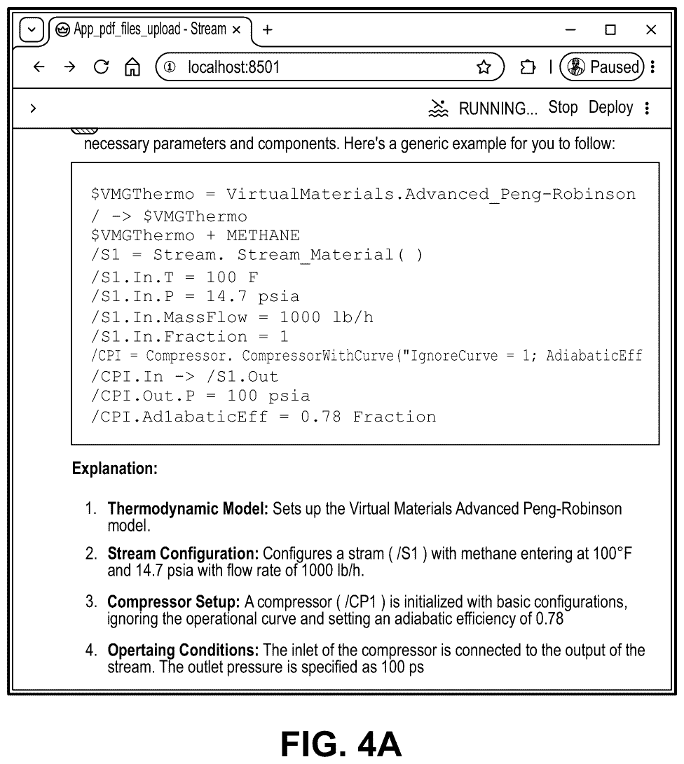

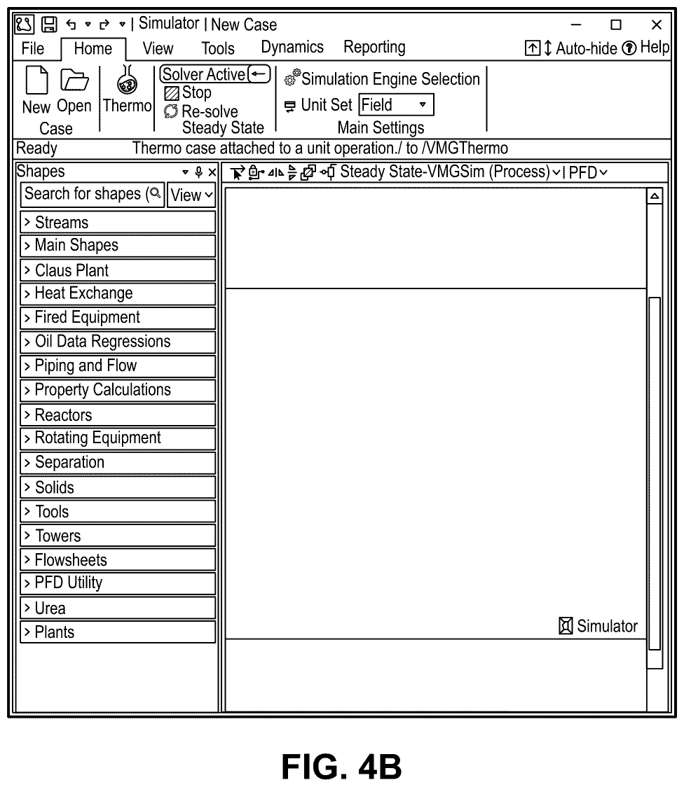

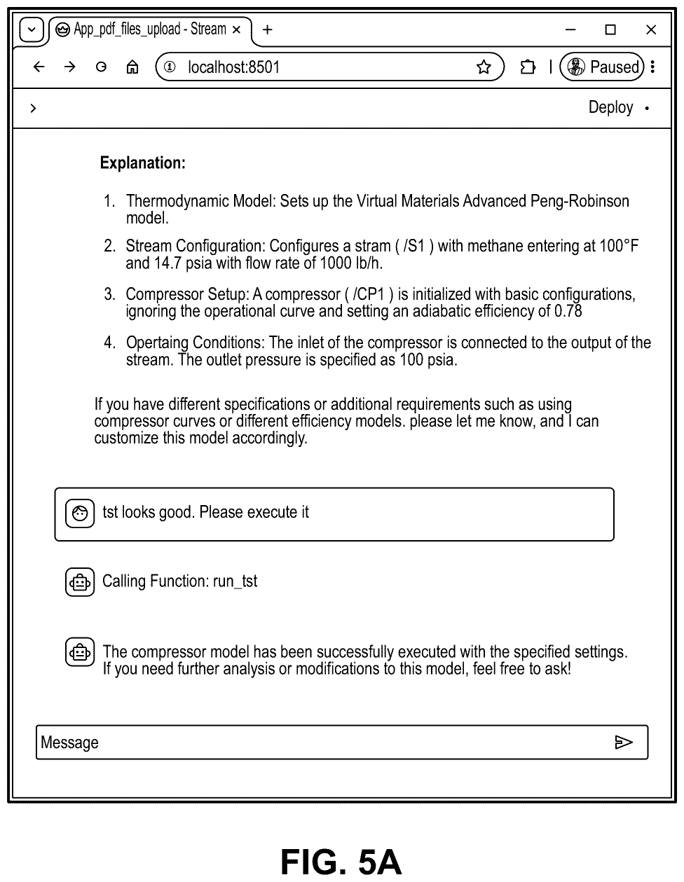

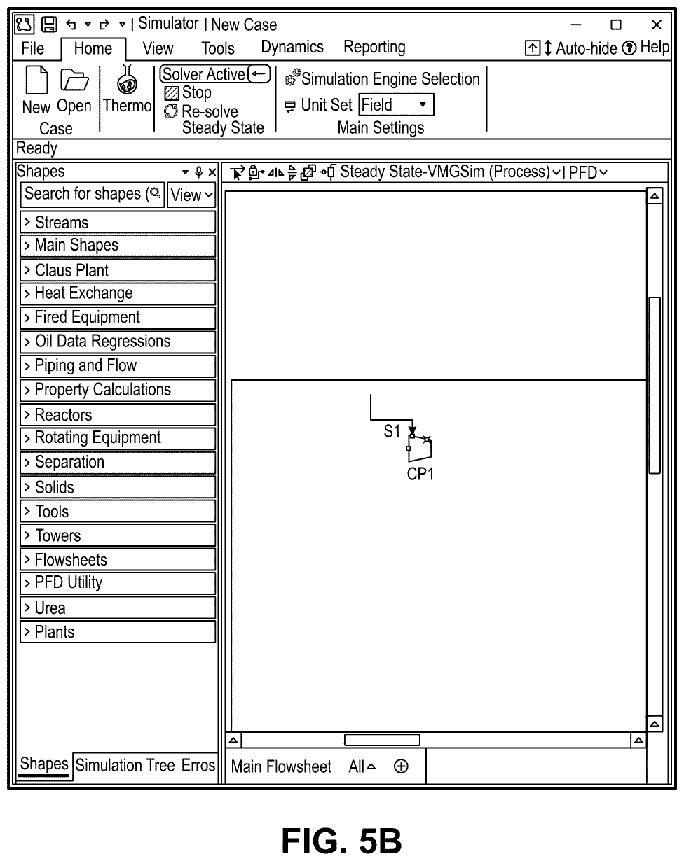

The same LLM can be driven by an orchestrating agent with similar requests. FIG. 2 illustrates a diagram of the components and the flow of information for the process simulation assistant, according to an embodiment. FIGS. 3A and 3B illustrate images of a user making a request to the assistant connected to the process simulator, according to an embodiment. FIGS. 4A and 4B illustrate images of the assistant proposing an action and explaining the action, according to an embodiment. FIGS. 5A and 5B illustrate the assistant being asked to perform the action and the creation of the simulation, according to an embodiment.

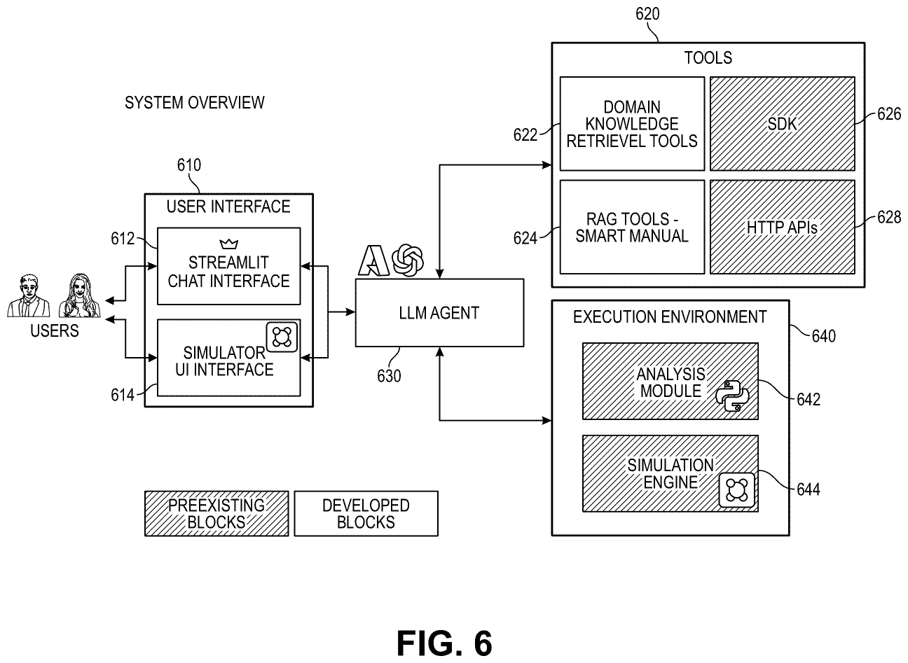

FIG. 6 illustrates a schematic view of a system 600 for creating a process simulation, according to an embodiment. The system 600 may include a user interface 610, tools 620, a LLM agent 630, and an execution environment 640. The user interface 610 may include a chat interface 612 and a simulator interface (e.g., Symmetry®) 614. The tools (also referred to as application(s)) 620 may include domain knowledge retrieval tools 622, RAG tools 624, an open source scripting language software development kit (e.g., Python®) 626, and an HTTP API module 628. The execution environment 640 may include an analysis, automation, and ML module (e.g., Python®) 642 and a simulator engine (e.g., Symmetry®) 644.

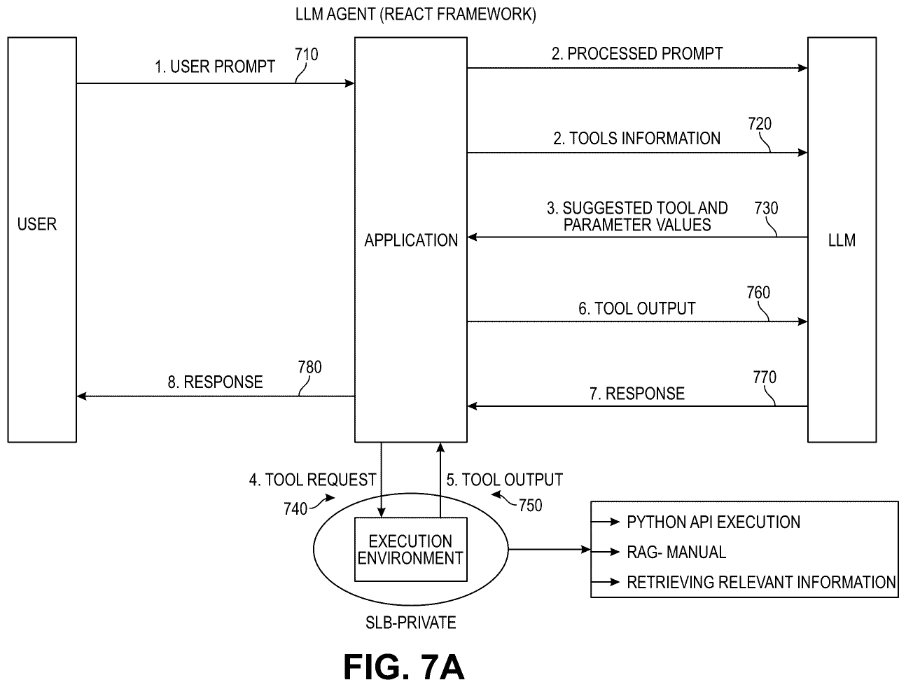

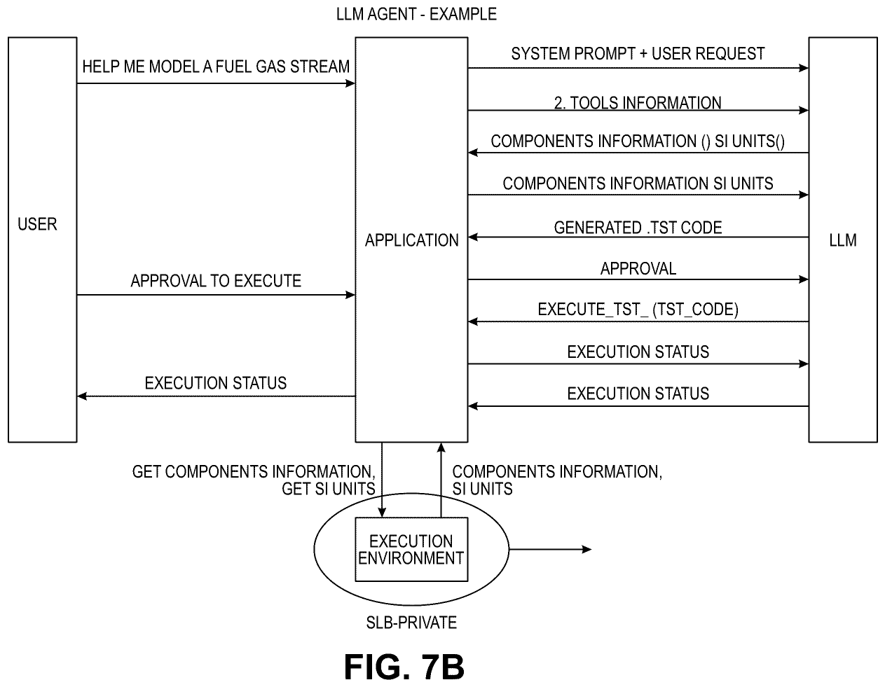

FIG. 7A illustrates the system 600 performing a general process simulation, and FIG. 7B illustrates the system 600 performing a specific example of a process simulation, according to an embodiment. As shown, a user prompt may be submitted from the user interface 610 to the application 620, as at 710. The application 620 may process the user prompt, and the processed user prompt and tools information may be transmitted from the application 620 to the LLM agent 630, as at 720. In response to the processed user prompt and/or tools information, suggested tool values and parameter values may then be generated and transmitted from the LLM agent 630 back to the application 620, as at 730. In response to the suggested tool values and parameter values, a tool request may be generated and transmitted from the application 620 to the execution environment 640, as at 740. In response to the tool request, a tool output may be generated and transmitted from the execution environment 640 to the application 620, as at 750. The application 620 may then transmit the tool output to the LLM agent 630, as at 760. In response to the tool output, the LLM agent 630 may generate and transmit a response to the application 620, as at 770. The application 620 may then transmit the response to the user interface 610, as at 780.

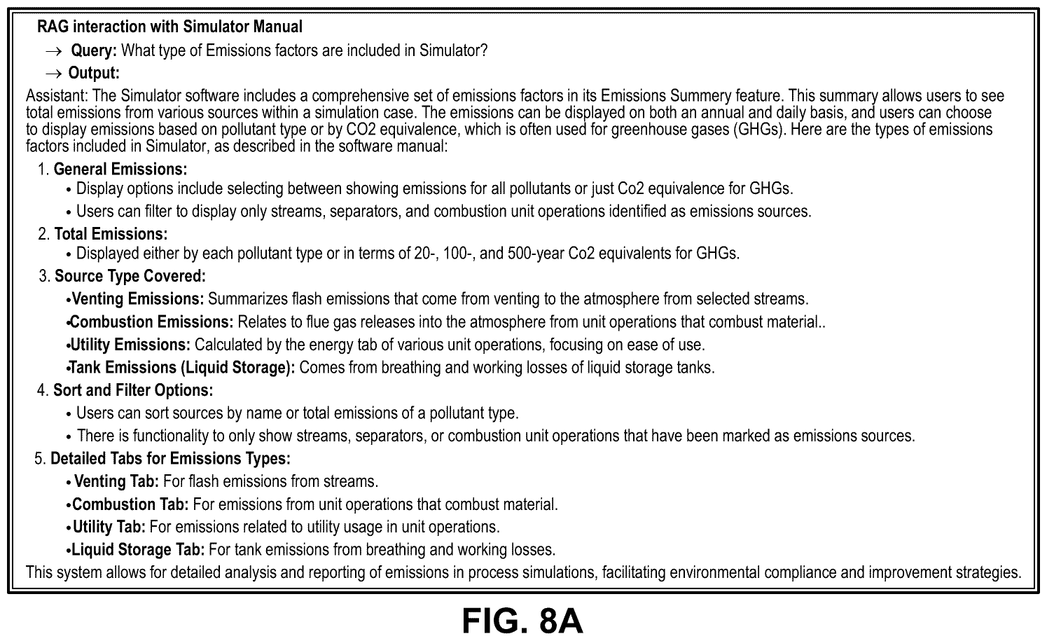

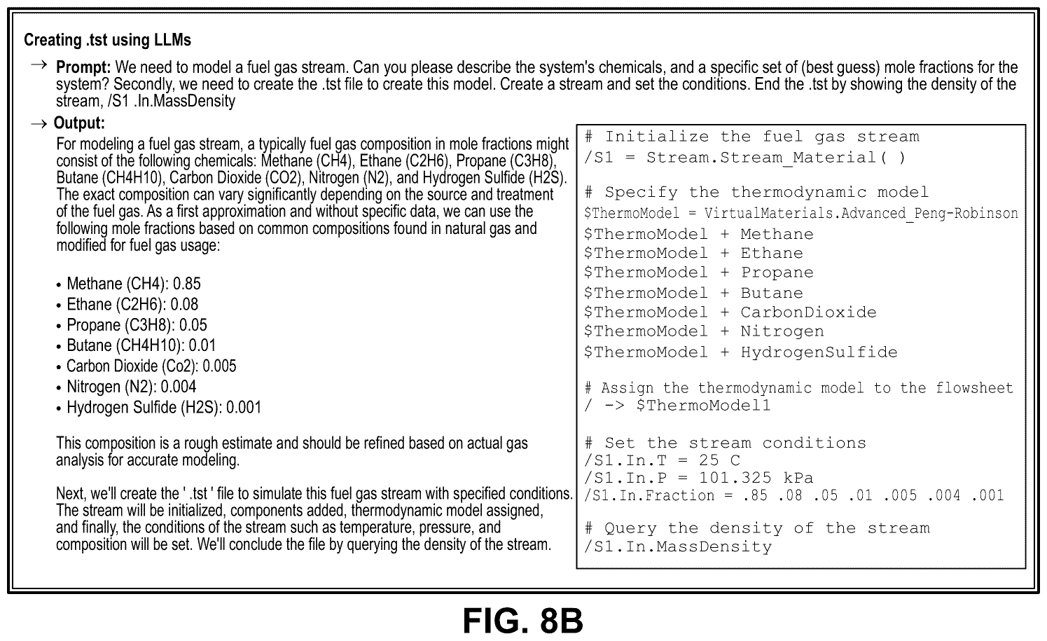

FIG. 8A illustrates an example of a simulator (e.g., Symmetry®) manual, and FIG. 8B illustrates an example of a model creation, according to an embodiment. Both FIGS. 8A and 8B show two different scenarios in which the assistant may be used. Each follows the steps outlined in FIG. 7A, and the outputs shown in FIGS. 8A and 8B may be generated accordingly. Internally, the tools used differ, so steps 730 to 760 in FIG. 7A may vary based on the internal reasoning performed by the agent. The results displayed in FIGS. 8A and 8B are the final responses received in step 770 of FIG. 7A, based on different queries submitted by the user in step 710.

### Exemplary Method

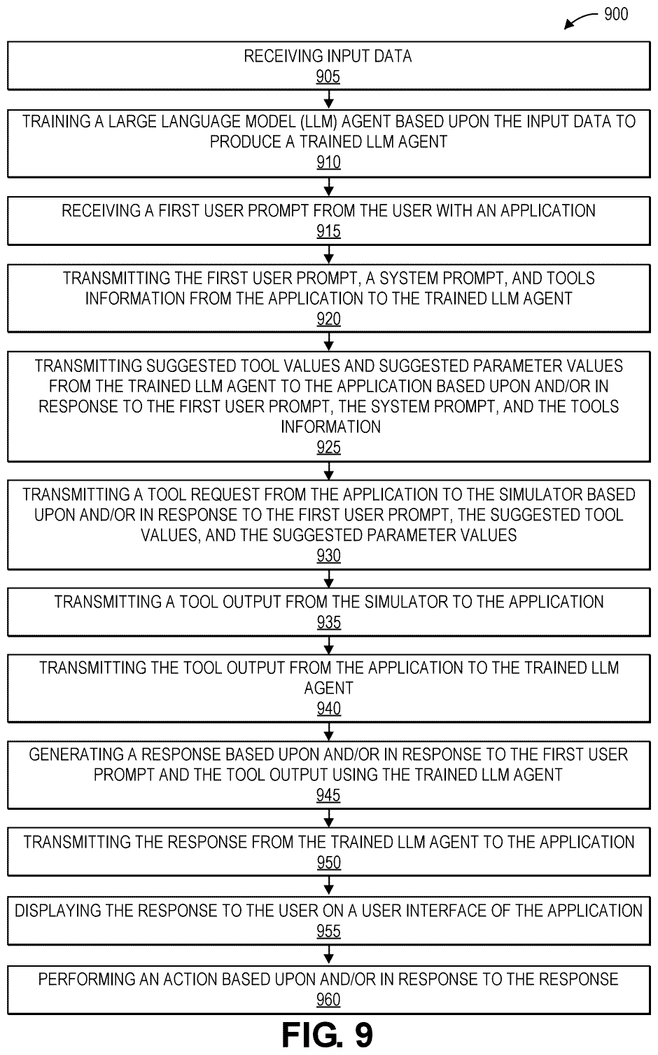

FIG. 9 illustrates a flowchart of a method 900 for simulating a process in a new or existing oil and/or gas processing facility, according to an embodiment. An illustrative order of the method 900 is provided below; however, one or more portions of the method 900 may be performed in a different order, simultaneously, repeated, or omitted. At least a portion of the method 900 may be performed using a computing system.

The method 900 may include receiving input data, as at 905. The input data may be related to the new or existing oil and/or gas processing facility. The input data may include text, voice, sound, and/or images. The input data may be received from a first artificial intelligence (AI) agent or from a user that is typing or talking into a microphone.

The method 900 may also include training a large language model (LLM) agent to reason and act based upon the input data to produce a trained LLM agent, as at 910.

The method 900 may also include receiving a first user prompt from the user with an application, as at 915. The first user prompt may include an instruction and/or a question related to the new or existing oil and/or gas processing facility. In an example, the instruction or the question may be related to simulating a plurality of different scenarios of dehydrating and conditioning of a natural gas stream to make it suitable for transport. In another example, the instruction or the question may be related to simulating a plurality of different scenarios of processing multiple crude feedstocks to produce one or more products that meet predetermined specifications. In yet another example, the instruction or the question may be related to simulating a plurality of different scenarios of determining emissions of equipment in response to using different energy sources.

The method 900 may also include transmitting the first user prompt, a system prompt, and/or tools information from the application to the trained LLM agent, as at 920. The system prompt may include instructions and/or guidelines for the trained LLM agent along with domain knowledge for a backend code of a simulator that (1) guides the trained LLM agent on how to behave for the different scenarios, (2) restricts a scope of the trained LLM agent to focus on a specific domain, and/or (3) acts as a safeguard for any vulnerable prompts.

The tools information may relate to different tools that are available. The tools may be used to fetch (e.g., request and/or receive) curated domain knowledge documents related to understanding different functionalities of different operations used in the new or the existing oil and/or gas processing facility. The curated domain knowledge documents may also be related to the backend code and properties of the different operations used in the new or the existing oil and/or gas processing facility supported by the simulator. The curated domain knowledge documents may include a user manual for the simulator. The tools may also fetch relevant portions from the curated domain knowledge documents by querying a vector store to determine a similarity score to rank a relevance of the portions. The tools may execute the backend code on the simulator by: (1) fetching a current state of the simulator; (2) generating the backend code based upon the first user prompt and the current state of the simulator; (3) executing the generated backend code to interact with the simulator using preexisting HTTP APIs and/or pre-existing SDK; and/or (4) generating follow-up scenarios in response to executing the generated backend code.

The method 900 may also include transmitting suggested tool values and/or suggested parameter values from the trained LLM agent to the application based upon and/or in response to the first user prompt, the system prompt, the tools information, or a combination thereof, as at 925. The suggested tool values may include names of the tools. The suggested parameter values may include values and specifications that guide behavior of the tools. The values may include the generated backend code. The values may also or instead include the name and the path of the variable and/or property that the user wants to know or update the value thereof, along with the specific unit system. The values may also or instead include a request to fetch the current state. The values may also or instead include the fetched current state of the simulator for reasoning before the generation of the backend code. The values may also or instead include the name of the component or functionality supported by the simulator that the LLM agent wants the curated knowledge for. The values may also or instead include a vector representation of the modified user query to find similar sections of the user manual.

The behavior (or behavior change) may include the tool executing the code through the servers using the (e.g., Python®) software development kit (SDK) or HTTP APIs in response to the value being the generated backend code. If the value is the name and path of variable and/or property, the relevant setting or fetch operations may be performed. The behavior (or behavior change) may also or instead include the current state being fetched using the (e.g., Python®) SDK. Based on the current state, the LLM agent may execute a generated (e.g., Python®) code to perform reasoning or else directly reason on the current state. The behavior (or behavior change) may also or instead include reading the appropriate file contents and returning the relevant information back to the LLM agent. The behavior (or behavior change) may also or instead include performing a similarity search and then returning the top-k similar chunks to help the LLM agent find relevant information.

The method 900 may also include transmitting a tool request from the application to the simulator based upon and/or in response to the first user prompt, the suggested tool values, the suggested parameter values, or a combination thereof, as at 930. The simulator may be configured to execute the backend code in response to the tool request.

The method 900 may also include transmitting a tool output from the simulator to the application, as at 935. The tool output may include responses from the tools.

The method 900 may also include transmitting the tool output from the application to the trained LLM agent, as at 940.

The method 900 may also include generating a response based upon and/or in response to the first user prompt and the tool output using the trained LLM agent, as at 945. The response may include text (1) summarizing the response, (2) describing one or more actions to be performed by the simulator, and/or (3) describing changes to make to the generated backend code.

The method 900 may also include transmitting the response from the trained LLM agent to the application, as at 950.

The method 900 may also include displaying the response to the user on a user interface of the application, as at 955.

The method 900 may also include performing an action based upon and/or in response to the response, as at 960. The action may be determined by the trained LLM agent. The action may be or include generating and/or transmitting a signal using the application that recommends, instructs, or causes a physical action to occur. The action may also or instead include performing the physical action. In an example, the physical action may include varying the dehydration and/or conditioning of the natural gas stream (e.g., using a glycol dehydration process, by increasing absorption using a physical solvent, by introducing a pipeline drip, etc.). In another example, the physical action may include varying the process for creating the crude feedstock (e.g., by introducing different elements, varying the concentrations of the elements, varying the temperature, varying the heat, etc.). In yet another example, the physical action may include switching energy sources to reduce the emissions of the equipment. In yet another example, the physical action may include selecting where to drill a wellbore, drilling the wellbore, varying a weight and/or torque on a drill bit that is drilling the wellbore, varying a drilling trajectory of the wellbore, varying a concentration and/or flow rate of a fluid pumped into the wellbore, or the like.

### Exemplary Computing System

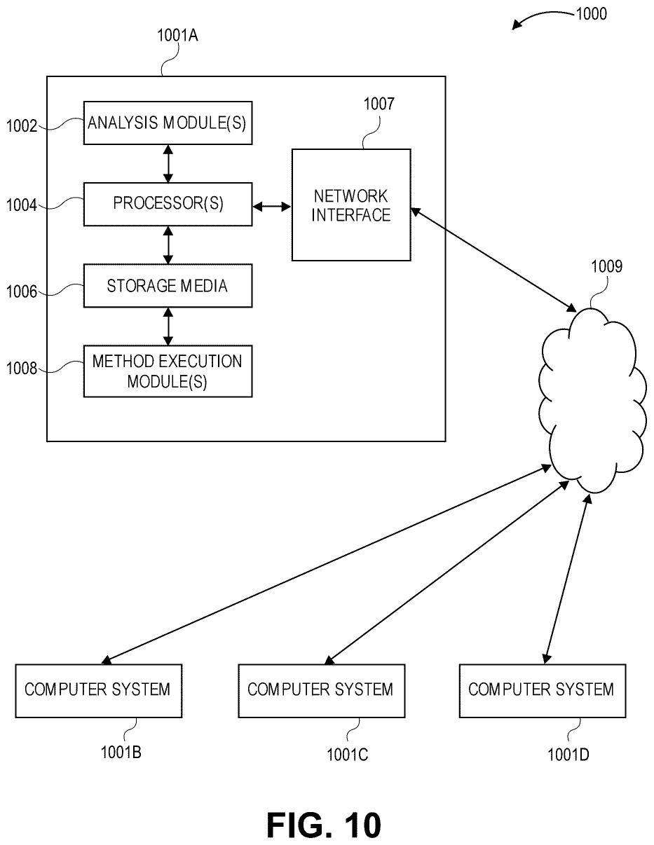

In some embodiments, the methods of the present disclosure may be executed by a computing system. FIG. 10 illustrates an example of such a computing system 1000, in accordance with some embodiments. The computing system 1000 may include a computer or computer system 1001A, which may be an individual computer system 1001A or an arrangement of distributed computer systems. The computer system 1001A includes one or more analysis modules 1002 that are configured to perform various tasks according to some embodiments, such as one or more methods disclosed herein. To perform these various tasks, the analysis module 1002 executes independently, or in coordination with, one or more processors 1004, which is (or are) connected to one or more storage media 1006. The processor(s) 1004 is (or are) also connected to a network interface 1007 to allow the computer system 1001A to communicate over a data network 1009 with one or more additional computer systems and/or computing systems, such as 1001B, 1001C, and/or 1001D (note that computer systems 1001B, 1001C and/or 1001D may or may not share the same architecture as computer system 1001A, and may be located in different physical locations, e.g., computer systems 1001A and 1001B may be located in a processing facility, while in communication with one or more computer systems such as 1001C and/or 1001D that are located in one or more data centers, and/or located in varying countries on different continents).

A processor may include a microprocessor, microcontroller, processor module or subsystem, programmable integrated circuit, programmable gate array, or another control or computing device.

The storage media 1006 may be implemented as one or more computer-readable or machine-readable storage media. Note that while in the example embodiment of FIG. 10 storage media 1006 is depicted as within computer system 1001A, in some embodiments, storage media 1006 may be distributed within and/or across multiple internal and/or external enclosures of computing system 1001A and/or additional computing systems. Storage media 1006 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 1000 contains one or more method execution module(s) 1008. In the example of computing system 1000, computer system 1001A includes the method execution module 1008. In some embodiments, a single method execution module may be used to perform some aspects of one or more embodiments of the methods disclosed herein. In other embodiments, a plurality of method execution modules may be used to perform some aspects of methods herein.

It should be appreciated that computing system 1000 is merely one example of a computing system, and that computing system 1000 may have more or fewer components than shown, may combine additional components not depicted in the example embodiment of FIG. 10, and/or computing system 1000 may have a different configuration or arrangement of the components depicted in FIG. 10. The various components shown in FIG. 10 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 1000, FIG. 10), and/or through manual control by a user who may make determinations regarding whether a given step, action, template, model, or set of curves has become sufficiently accurate for the evaluation of the subsurface three-dimensional geologic formation under consideration.

The foregoing description, for purposes of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

What is claimed is:

1. A method for simulating a process in a new or existing oil and/or gas processing facility, the method comprising:
receiving a user prompt from a user with an application;
transmitting the user prompt from the application to a trained large language model (LLM) agent;
transmitting suggested tool values and/or suggested parameter values from the trained LLM agent to the application based upon and/or in response to the user prompt;
transmitting a tool request from the application to a simulator based upon and/or in response to the suggested tool values and/or the suggested parameter values;
transmitting a tool output from the simulator to the application to the trained LLM agent based upon and/or in response to the tool request; and
generating a response based upon and/or in response to the user prompt and the tool output using the trained LLM agent.

2. The method of claim 1, further comprising:
receiving input data, wherein the input data is related to the new or existing oil and/or gas processing facility, wherein the input data comprises text, voice, sound, and/or images, and wherein the input data is received from an artificial intelligence (AI) agent or from the user that is typing or talking into a microphone; and
training a LLM agent to reason and act based upon the input data to produce the trained LLM agent.

3. The method of claim 1, wherein the user prompt comprises an instruction or a question related to the new or existing oil and/or gas processing facility, wherein the instruction or the question is related to simulating a plurality of different scenarios of dehydrating and conditioning of a natural gas stream to make it suitable for transport.

4. The method of claim 1, wherein the user prompt comprises an instruction or a question related to the new or existing oil and/or gas processing facility, wherein the instruction or the question is related to simulating a plurality of different scenarios of processing multiple crude feedstocks to produce one or more products that meet predetermined specifications.

5. The method of claim 1, wherein the user prompt comprises an instruction or a question related to the new or existing oil and/or gas processing facility, wherein the instruction or the question is related to simulating a plurality of different scenarios of determining emissions of equipment in response to using different energy sources.

6. The method of claim 1, wherein the user prompt, a system prompt, and tools information are transmitted from the application to the trained LLM agent, wherein the suggested tool values and the suggested parameter values are transmitted based upon and/or in response to the user prompt, the system prompt, and the tools information, wherein the suggested tool values comprise names of tools that are available to use, and wherein the suggested parameter values comprise values and specifications that guide behavior of the tools.

7. The method of claim 1, wherein the simulator is configured to execute a backend code in response to the tool request.

8. The method of claim 7, wherein the response comprises text summarizing the response, describing one or more actions to be performed by the simulator, and describing changes to make to the generated backend code.

9. The method of claim 1, further comprising displaying the response to the user on a user interface of the application.

10. The method of claim 1, further comprising performing an action based upon and/or in response to the response, wherein the action is determined by the trained LLM agent, and wherein the action comprises generating and/or transmitting a signal using the application that recommends, instructs, or causes a physical action to occur in the new or existing oil and/or gas processing facility.

11. A computing system, comprising:
one or more processors; and
a memory system comprising one or more non-transitory computer-readable media storing instructions that, when executed by at least one of the one or more processors, cause the computing system to perform operations, the operations comprising:
receiving a user prompt from a user with an application;
transmitting the user prompt from the application to a trained LLM agent;
transmitting suggested tool values and suggested parameter values from the trained LLM agent to the application based upon and/or in response to the user prompt;
transmitting a tool request from the application to a simulator based upon and/or in response to the suggested tool values and the suggested parameter values;
transmitting a tool output from the simulator to the application to the trained LLM agent based upon and/or in response to the tool request; and
generating a response based upon and/or in response to the user prompt and the tool output using the trained LLM agent.

12. The computing system of claim 11, wherein a system prompt and tools information are transmitted along with the user prompt from the application to the trained LLM agent, and wherein the system prompt comprises instructions and guidelines for the trained LLM agent along with domain knowledge for a backend code of the simulator that (1) guides the trained LLM agent on how to behave for the different scenarios, (2) restricts a scope of the trained LLM agent to focus on a specific domain, and (3) acts as a safeguard for any vulnerable prompts.

13. The computing system of claim 12, wherein the tools information relates to different tools that are available.

14. The computing system of claim 13, wherein the tools are used to fetch curated domain knowledge documents related to understanding different functionalities of different operations used in a new or the existing oil and/or gas processing facility.

15. The computing system of claim 14, wherein the curated domain knowledge documents are also related to the backend code and properties of the different operations used in the new or the existing oil and/or gas processing facility supported by the simulator.

16. A non-transitory computer-readable medium storing instructions that, when executed by one or more processors of a computing system, cause the computing system to perform operations, the operations comprising:
receiving a user prompt from a user with an application;
transmitting the user prompt from the application to a trained LLM agent;
transmitting suggested tool values and suggested parameter values from the trained LLM agent to the application based upon and/or in response to the user prompt;
transmitting a tool request from the application to a simulator based upon and/or in response to the suggested tool values and the suggested parameter values;
transmitting a tool output from the simulator to the application to the trained LLM agent based upon and/or in response to the tool request; and
generating a response based upon and/or in response to the user prompt and the tool output using the trained LLM agent.

17. The non-transitory computer-readable medium of claim 16, wherein a system prompt and tools information are transmitted along with the user prompt from the application to the trained LLM agent, wherein the tools information relates to different tools that are available, and wherein the tools are used to fetch curated domain knowledge documents.

18. The non-transitory computer-readable medium of claim 17, wherein the curated domain knowledge documents comprise a user manual for the simulator.

19. The non-transitory computer-readable medium of claim 17, wherein the tools also fetch relevant portions from the curated domain knowledge documents by querying a vector store to determine a similarity score to rank a relevance of the portions.

20. The non-transitory computer-readable medium of claim 17, wherein the tools execute a backend code on the simulator by:
fetching a current state of the simulator;
generating the backend code based upon the user prompt and the current state of the simulator;
executing the generated backend code to interact with the simulator, and
generating follow-up scenarios in response to executing the generated backend code.
